(19) United States
(12) Patent Application Publication
(10) Pub. No.: US 2003/0115523 A1
(43) Pub. Date: Jun. 19, 2003

(54) Apparatus and method for analysis and troubleshooting of electronic devices

(76) Inventors: Reuven Lavie, Hertzelia (IL); Avi Costo, Haifa (IL)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/020,200

(22) Filed: Dec. 18, 2001

(51) Int. Cl. G01R 31/28

(52) U.S. Cl. 714/726

(57) ABSTRACT

An apparatus and method for trouble shooting devices contained within a digital electronic system using external test equipment and scan module contained within the devices. Upon receipt of an external event trigger by the scan module, the operations of the device are halted. The contents of the flip-flops contained within the device are held constant. Thereafter, the contents of the flip-flops may be transmitted serially from the device to the external test equipment. Communication lines between the external test equipment and the device may be embedded within a baseboard in which the devices are attached.

### FIELD

The invention relates to an apparatus and method for analysis and troubleshooting of electronic devices. More particularly, the present invention is an apparatus and method for the retrieving the contents of flip-flops within a chip at any given clock cycle through an external interface.

### BACKGROUND

In the rapid development of computers many advancements have been seen in the areas of processor speed, throughput, communications, fault tolerance and size of individual components. Today's microprocessors, memory and other chips have become faster and smaller. However, with the increase in speed, reduction in the size of components, and increased density of circuitry found within a given chip, no device and method is provided to analyze, diagnose and troubleshoot problems that may exist within an individual chip once it is fully assembled and possibly installed in a computer system.

Throughout the design and production of a device such as, but not limited to, a microprocessor, memory controller, peripheral interface, and communications interface, extensive testing occurs of the logic, design, prototype, and throughout the manufacturing process of the final product. For example, during the design phase of a microprocessor the circuitry and logic of the microprocessor are simulated and thoroughly tested. Further, once a prototype is built, diagnostics are run on the prototype that attempt to simulate the real world operations of the prototype and identify any possible problems in logic or manufacture that may exist. Once a device goes into manufacture, extensive testing is performed throughout the entire manufacturing process to assure each components operating properly. However, once a device, such as a chip, is assembled there is no method for analyzing the state of the chip at any given clock cycle. More specifically, no method or device exists for determining the values contained in flip-flops and registers for any given clock cycle once the chip is manufactured and fully assembled.

Methods utilized to troubleshoot a chip include running diagnostics on the chip. However, the diagnostics would only indicate that a specific problem exists on the chip and not necessarily identify the logic or element in which the problem exists. As a last resort the chip may be dismantled and probes placed in contact with specific circuits on the chip. The probes would be hooked up to diagnostic equipment such as logic analyzers and/or computers. The attachment of the probes would have to be done utilizing a microscope. This approach is of course extremely difficult and may not necessarily produce the desired results since the act of attaching probes to circuits on a chip will often affect its timing and produce other problems or mask the existing problem. Further, this approach is extremely difficult and time consuming and therefore a very expensive troubleshooting mechanism.

Therefore, what is required is an apparatus and method that will allow access to flip-flops and/or registers contained within the chip without the need for dismantling the chip. This method and apparatus should be able to retrieve the values of all flip-flops contained within the chip at a user determined clock cycle. Therefore, a user should be able to see snapshots of flip-flops on a cycle by cycle basis and determine how the chip is operating and the likely location of a logic or manufacturing problem.

### BRIEF DESCRIPTION OF THE DRAWINGS

The foregoing and a better understanding of the present invention will become apparent from the following detailed description of exemplary embodiments and the claims when read in connection with the accompanying drawings, all forming a part of the disclosure of this invention. While the foregoing and following written and illustrated disclosure focuses on disclosing example embodiments of the invention, it should be clearly understood that the same is by way of illustration and example only and the invention is not limited thereto. The spirit and scope of the present invention are limited only by the terms of the appended claims.

The following represents brief descriptions of the drawings, wherein:

FIG. 1 is an example of a digital electronic system in which components contain a scan module in an example embodiment of the present invention;

FIG. 2 is a system diagram illustrating the connections between the scan module and external test equipment in an example embodiment of the present invention;

FIG. 3 is a block diagram illustrating the connections between the scan module and device core in an example embodiment of the present invention;

FIG. 4 is a block diagram illustrating the operation of the device core connected to a synchronous scan control module in an example embodiment of the present invention;

FIG. 5 is a block diagram illustrating the operation of the device core during a scanning operation initiated by external test equipment in an example embodiment of the present invention; and

FIG. 6 is a flowchart of the process utilized to initiate a scanning of all flip-flops in a device and the storing and reporting of the contents of the flip-flops in an example embodiment of the present invention.

### DETAILED DESCRIPTION

Before beginning a detailed description of the subject invention, mention of the following is in order. When appropriate, like reference numerals and characters may be used to designate identical, corresponding or similar components in differing figure drawings. Further, in the detailed description to follow, exemplary sizes/models/values/ranges may be given, although the present invention is not limited to the same. As a final note, well-known components of computer networks may not be shown within the FIGS. for simplicity of illustration and discussion, and so as not to obscure the invention.

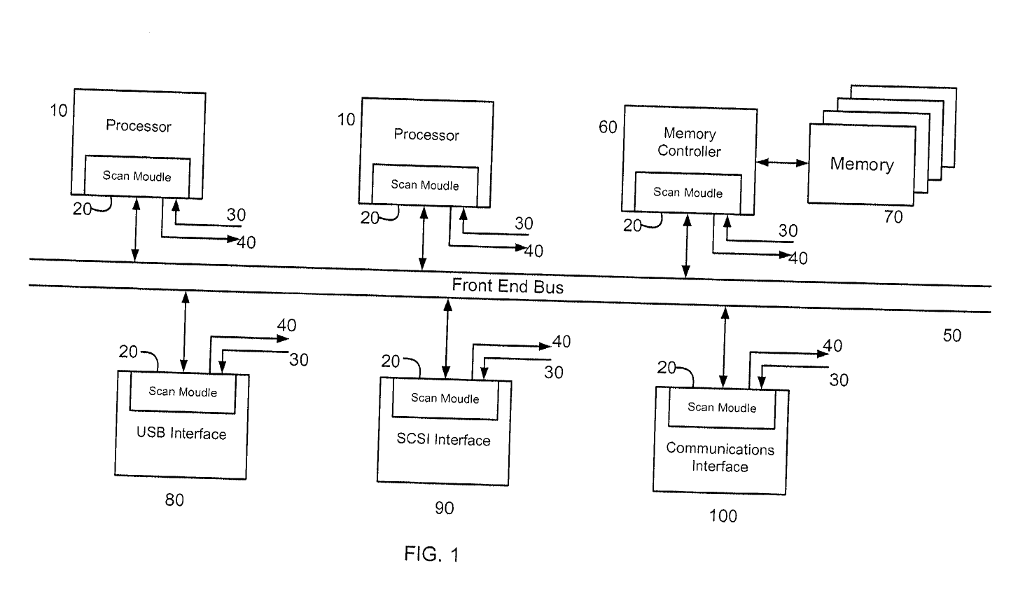

FIG. 1 is an example of a digital electronic system in which components contain a scan module 20 in an example embodiment of the present invention. As would be appreciated by one of ordinary skill in the art, the digital electronic system illustrated in FIG. 1 is merely an example configuration of a possible digital electronic system. The configuration of the digital electronic system may be altered to include any number of processors and front end buses 50, memory controller 60, communications interface 100, and other peripheral controllers and bus interfaces. Therefore, it is not the intent of this specification to restrict the present invention to the example digital electronic system shown in FIG. 1. Thus, FIG. 1 is merely supplied as a simplified example to illustrate that scan module 20 may be included in any number and type of devices included within a digital electronic system.

Still referring to FIG. 1, a total of six devices are shown interfacing to a front-end bus 50. These devices include two processors 10, a memory controller 60 interfacing to memory 70, a universal serial bus (USB) interface 80, a small computer system interface (SCSI) 90, and a communications interface 100. Each component illustrated in FIG. 1 is collectively referred to as device(s). Each device has a scan module 20 contained therein. The scan modules 20 are incorporated in each device during manufacturing in order to test the respective device during the manufacturing process. Until the example embodiments of the present invention, the scan module 20 was not used after the device has been manufactured. In normal operation of the digital electronic system, the scan module 20 would not be active and would not influence the operation of the digital electronic system. Communications with the scan module 20 may utilize an external event trigger signal 30 and scan chain signal 40. Both the external event trigger signal 30 and scan chain signal 40 may be incorporated in the baseboard (motherboard) in which the front and bus 50 would be embedded and the devices shown in FIG. 1 attached thereto. As will be discussed in further detail ahead, upon receipt of an external event trigger signal 30 the scan module 20 would freeze the operation of the device and begin serial transmission of the contents of the device over scan chain signal 40.

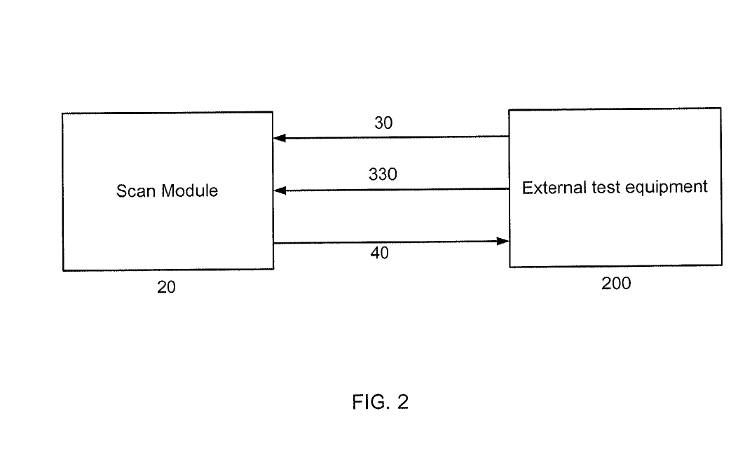

FIG. 2 is a system diagram illustrating the connections between the scan module 20 and external test equipment 200 in an example embodiment of the present invention. As previously discussed in FIG. 1, the scan module 20 would be contained within each device on the digital electronic system illustrated in FIG. 1. The external test equipment 200 comprises any processor based system including, but not limited to, a computer system, personal computer, palm computer, and logic analyzer. The external test equipment 200 would generate the external event trigger signal 30 which would be received by the scan module 20. The external test equipment 200 may also generate the scan clock signal 330 which would synchronize the activities of the device during scan mode operations, as discussed in further detail ahead. Once scan mode is engaged, the external test equipment 200 would receive a serial bit stream from scan chain signal 40. As will be discussed in further detail ahead, the external test equipment 200 would present to the user the received data from the device.

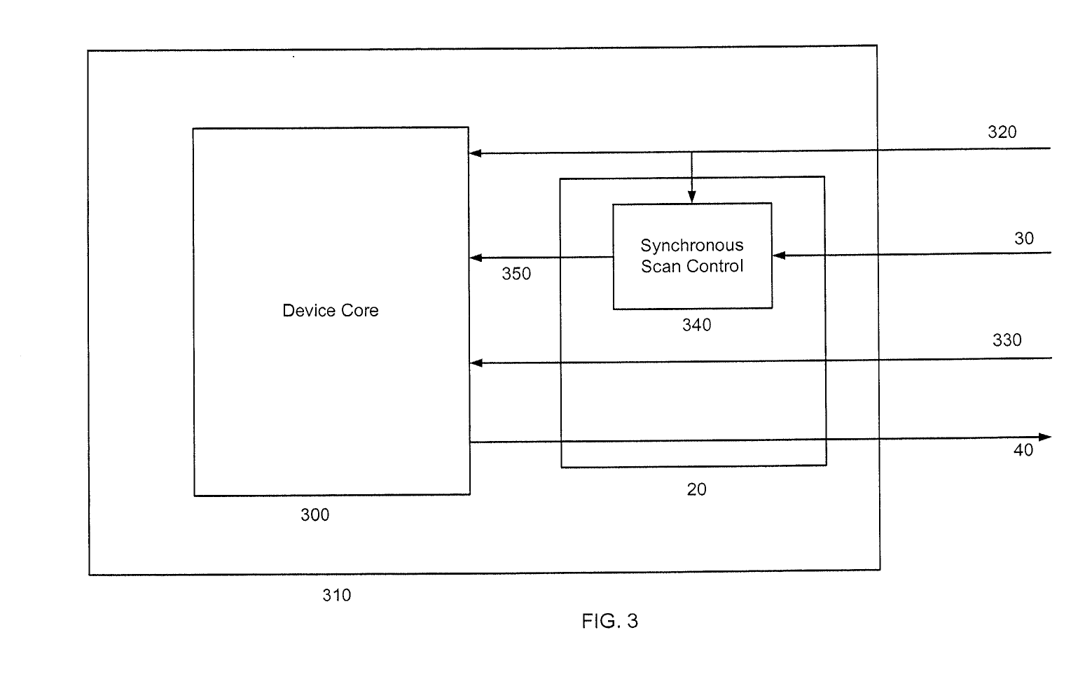

FIG. 3 is a block diagram illustrating the connections between the scan module 20 and device core 300 in an example embodiment of the present invention. As previously discussed, scan module 20 would be contained within devices 310 illustrated in, but not limited to, FIG. 1. In the case where device 310 is a processor 10, as illustrated in FIG. 1, device core 300 may contain all the elements required by a processor 10 to perform its functions. Contained within scan module 20 would be a synchronous scan control module 340 which would receive the external event trigger signal 30 from the external test equipment 200, previously discussed in reference to FIG. 2. Upon receipt of the external event trigger signal 30 the synchronous scan control module 340 would generate a synchronous scan command 350 to the device core 300 that would cause the device core to cease operations and freeze the contents of any flip-flops or registers contained therein. The synchronous scan control module 340 would receive the same operational clock signal 320 used to synchronize all devices 310 in the digital electronic system illustrated in FIG. 1. This operational clock signal 320 would also be input to device core 300 so that the device core 300 of devices 310 would be synchronized with the other devices 310 in the digital electronic system shown in FIG. 1. In addition, the scan clock signal 330 would be input to the device core and scan module 20 from the external test equipment 330 in order to synchronize the transmission of data from the device core to the external test equipment 200 via the scan chain signal 40.

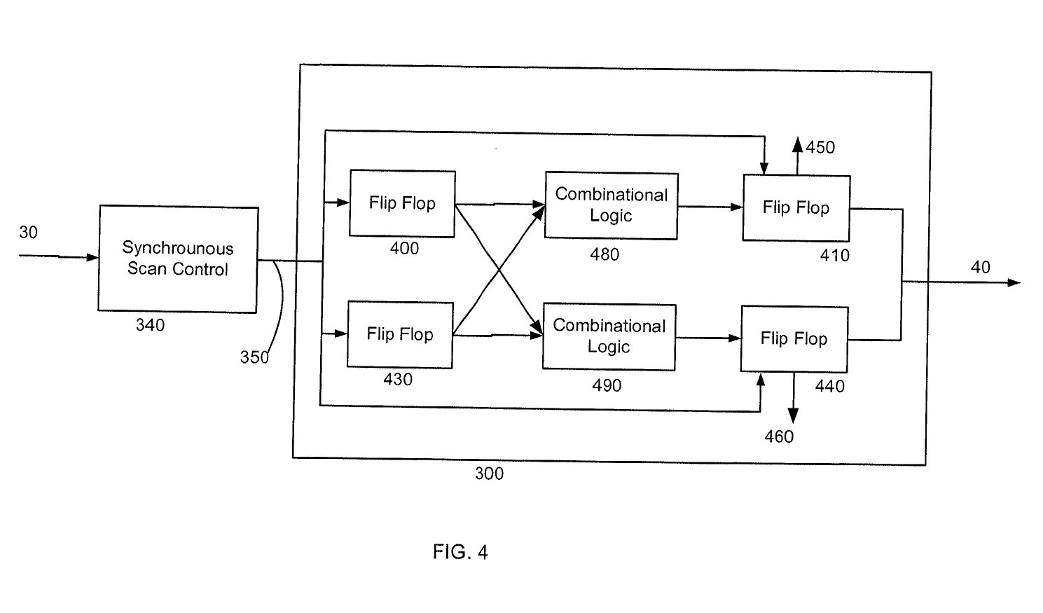

FIG. 4 is a block diagram illustrating the operation of the device core 300 connected to a synchronous scan control module 340 via synchronous scan command signal 350 in an example embodiment of the present invention. In the example embodiment provided in FIG. 4, the synchronous scan control module 340 has not received in external event trigger 30 from the external test equipment 200. Therefore, the synchronous scan command signal 350 has not been activated and serial output from the scan chain signal 40 is not being transmitted to the external test equipment 200. It should be noted that the device core 300 could be operating as required by the nature of device 310. Flip-flops 400, 410, 430, 440 may be interconnected as illustrated in FIG. 4 utilizing combinational logic units 480 and 490. Combinational logic units 480 and 490 would receive data from flip-flops 400 and/or 410 and transmit the data to flip-flops 410 and 440. As would be appreciated by one of ordinary skill in the art, the precise interconnection of flip-flops 400 through 440 and combinational logic units 480 and 490 would depend upon the specific design of device core 300 and device 310. Therefore, FIG. 4 is provided merely as an example of how a device core 300 may be designed. Further, output from flip-flop 410 maybe redirected with in device core 300 via signal 450 and output from flip-flop 440 maybe redirected within device core 300 via signal 460.

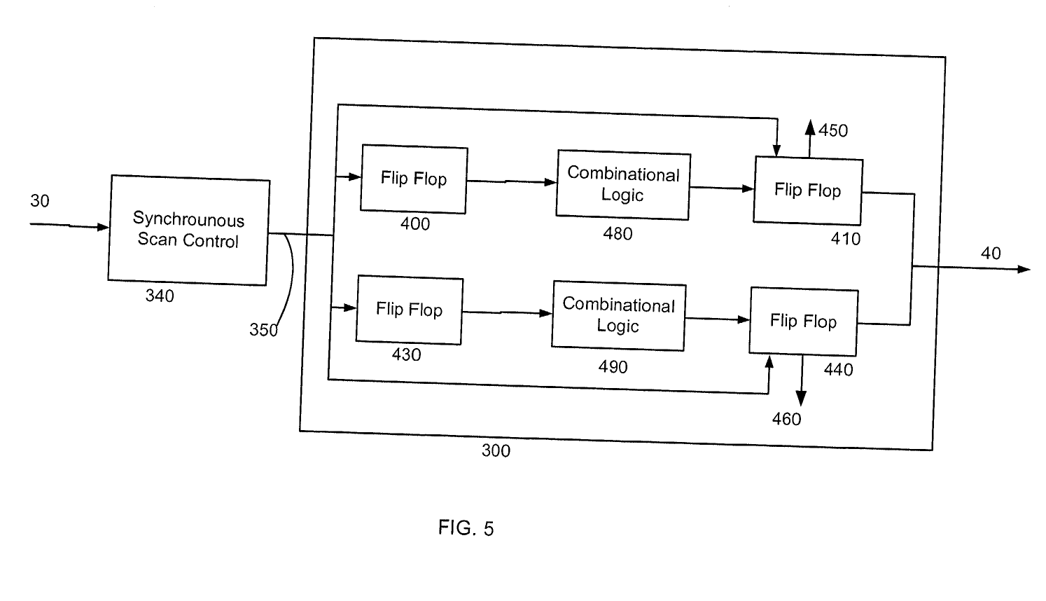

FIG. 5 is a block diagram illustrating the operation of the device core 300 during a scanning operation initiated by external test equipment 200 in an example embodiment of the present invention. It should be noted that FIG. 5 differs from FIG. 4 in that flip-flop 400 and combinational logic unit 480 are no longer illustrated as interconnected as well as flip-flop 430 and combination logic unit 490. This absence of interconnection is intended to illustrate that these flip-flops and combinational logic units are no longer communicating to each other, but the physical connections are intact.

Still referring to FIG. 5, upon receipt of external event trigger signal 30 the synchronous scan control module 340 would generate a synchronous scan command signal 350 that would cause all flip-flops within device core 300 to hold operations, retain contents, and serially transmits the contents of each flip-flop to external test equipment 200 via scan chain signal 40. As previously discussed the mechanism of operation of the synchronous scan control module 340 remains unchanged from that used in the manufacturing process. However, using the external event trigger signal 30 and receiving data for the scan chain signal 40, it is possible for external test equipment 200 to be utilized in a non-manufacturing environment and after the device 310 has been completed and possibly installed in a digital electronic system. Once scan mode operations have commenced, signals 450 and 460 would not be utilized even though the physical connections remain.

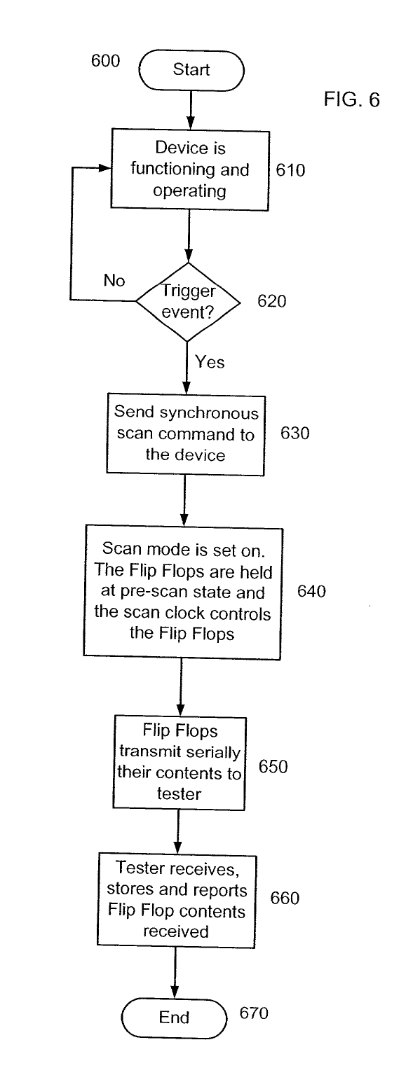

Before proceeding into a detailed discussion of the logic used by the embodiments of the present invention it should be mentioned that the flowchart shown in FIG. 6 may contain software, firmware, hardware, processes or operations that correspond, for example, to code, sections of code, instructions, commands, objects, hardware or the like, of a computer program that is embodied, for example, on a storage medium such as floppy disk, CD Rom, EP Rom, RAM, hard disk, etc. Further, the computer program can be written in any language such as, but not limited to, for example C++.

FIG. 6 is a flowchart of the process utilized to initiate a scanning of all flip-flops in a device 310 and the storing and reporting of the contents of the flip-flops in an example embodiment of the present invention. Processing begins execution in operation 600 and immediately proceeds to operation 610. In operation 610 device 310 would be embedded in a digital electronic system, as illustrated in FIG. 1, and maybe executing some function. In operation 320 it is determined if an external event trigger signal 30 has occurred. If an external event trigger signal 30 has not occurred then processing loops back to operation 610. However, if an external event trigger signal 30 has occurred then processing proceeds to operation 630. The external event trigger signal 30 may be generated by external test equipment 200 and received by the synchronous scan control module 340. In operation 630, the synchronous scan control module 340 would set the synchronous scan command signal 350 to an on state. Processing then proceeds to operation 640 were the scan mode is set on and the flip-flops in the device core 300 are held at a pre-scan state. The scan clock signal 330 is utilized to control the flip-flops from this point forward so that the device 310 is now synchronized with the external test equipment 200. In operation 650, the flip-flops transmits serially their contents to the external test equipment 200. Thereafter, in operation 660 the external test equipment 200 receives, stores, and reports the contents of the flip-flops received to the user. Processing then proceeds to operation 670 where processing terminates.

The benefit resulting from the present invention is that a simple device and method is provided for accessing the contents of a device without the need to take the device apart and attach probes thereto. Therefore, it is possible for a user to examine the contents of a processor or other device at each clock cycle so as to troubleshoot that processor or device without removing it from the digital electronic system.

While we have shown and described only a few examples herein, it is understood that numerous changes and modifications as known to those skilled in the art could be made to the example embodiment of the present invention. Therefore, we do not wish to be limited to the details shown and described herein, but intend to cover all such changes and modifications as are encompassed by the scope of the appended claims.

We claim:

1. A method of trouble shooting a device in a digital electronic system, comprising:
transmitting an external event trigger signal to a scan module to began a scan operation in the device;
transmitting a synchronous scan command signal to a device core in the device;
holding values contained in the plurality of flip-flops in the device core unchanged when the synchronous scan command signal is received by the device core; and
transmitting the values contained in the plurality of flip-flops to external test equipment when the synchronous scan command signal is received.

2. The method recited in claim 1, wherein the transmitting an external event trigger signal to a scan module to began a scan operation in the device, further comprises:
connecting the external test equipment to the external event trigger signal and a scan chain signal, wherein the external event trigger signal and the scan chain signal are embedded in a baseboard in which the device is connected.

3. The method recited in claim 2, wherein the transmitting the values contained in the plurality of flip-flops to external test equipment when the synchronous scan command signal is received, further comprises:
transmitting serially the values contained in the plurality of flip-flops to the external test equipment over the scan chain signal, wherein ordering the flip-flops is dependent upon the type of device being scanned.

4. The method recited in claim 3, further comprises:
receiving and the values contained in the plurality of flip-flops serially by the external test equipment;
storing the values contained in the plurality of flip-flops; and
reporting to the user the values contained in the plurality of flip-flops by the external test equipment.

5. The method recited in claim 4, wherein holding values contained in the plurality of flip-flops in the device core unchanged when the synchronous scan command signal is received by the device core, further comprises:
synchronizing the plurality of flip-flops in the device core using a scan clock signal generated by the external test equipment.

6. The method recited in claim 5, further comprises:
controlling the transmission timing of the values contained by the plurality of flip-flops to the external test equipment based upon the scan clock signal.

7. The method recited in claim 6, wherein the device comprises a processor, memory controller, USB interface, SCSI interface, or communications interface.

8. A computer program embodied on a computer readable medium and executable by a computer for trouble shooting a device in a computer system, comprising:
transmitting an external event trigger signal to a scan module to began a scan operation in the device;
transmitting a synchronous scan command signal to a device core in the device;
holding values contained in the plurality of flip-flops in the device core unchanged when the synchronous scan command signal is received by the device core; and
transmitting the values contained in the plurality of flip-flops to external test equipment when the synchronous scan command signal is received.

9. The computer program recited in claim 8, wherein the transmitting an external event trigger signal to a scan module to began a scan operation in the device, further comprises:
connecting the external test equipment to the external event trigger signal and a scan chain signal, wherein the external event trigger signal and the scan chain signal are embedded in a baseboard in which the device is connected.

10. The computer program recited in claim 9, wherein the transmitting the values contained in the plurality of flip-flops to external test equipment when the synchronous scan command signal is received, further comprises:
transmitting serially the values contained in the plurality of flip-flops to the external test equipment over the scan chain signal, wherein ordering the flip-flops is dependent upon the type of device being scanned.

11. The computer program recited in claim 10, further comprises:
receiving and the values contained in the plurality of flip-flops serially by the external test equipment;
storing the values contained in the plurality of flip-flops; and
reporting to the user the values contained in the plurality of flip-flops by the external test equipment.

12. The computer program recited in claim 11, wherein holding values contained in the plurality of flip-flops in the device core unchanged when the synchronous scan command signal is received by the device core, further comprises:
synchronizing the plurality of flip-flops in the device core using a scan clock signal generated by the external test equipment.

13. The computer program recited in claim 12, further comprises:
controlling the transmission timing of the values contained by the plurality of flip-flops to the external test equipment based upon the scan clock signal.

14. The computer program recited in claim 13, wherein the device comprises a processor, memory controller, USB interface, SCSI interface, or communications interface.

15. An apparatus to retrieve contents of a plurality of flip-flops contained within a device in a digital electronic system, comprising:
an external test equipment to transmit an external event trigger signal and receive the contents of the plurality of flip-flops;
a scan module embedded in the device and connected to the external test equipment to receive the external event trigger signal and transmit the contents of the plurality of flip-flops when the external event trigger signal is set on, wherein the external event trigger signal is embedded in a baseboard in which the device is attached to.

16. The apparatus recited in claim 15, further comprising:
a scan chain signal to connect the device to the external test equipment, wherein the contents of the plurality of flip-flops is transmitted to the external test equipment from the device over the scan chain signal in a serial manner.

17. The apparatus recited in claim 16, further comprising:
a scan clock signal generated by the external test equipment and connected to the device to synchronize the transmission of the contents of the proud to flip-flops over the scan chain signal.

18. The apparatus recited in claim 17, wherein the scan module further comprises
a synchronous scan command module to generate a synchronous scan command signal to a device core contained within the device and having the plurality of flip-flops contained in the device core, wherein when the synchronous scan command signal is received the contents of the plurality of flip-flops is held constant.

19. The apparatus recited in claim 18, wherein when the synchronous scan command signal is received by the device core operations of the device are halted

20. The apparatus recited in claim 19, wherein the external test equipment will store and display the contents of the flip-flops upon receipt from the device.

21. The apparatus recited in claim a 20, wherein the wherein the device comprises a processor, memory controller, USB interface, SCSI interface, or communications interface.
